(19) United States
(12) Patent Application Publication
(10) Pub. No.: US 2023/0010525 A1
(43) Pub. Date: Jan. 12, 2023

(54) ARTIFICIAL ANTIFERROMAGNETIC STRUCTURE AND STORAGE ELEMENT

(71) Applicant: SHANDONG UNIVERSITY, Jinan (CN)

(72) Inventors: Shishen YAN, Jinan (CN); Yufeng TIAN, Jinan (CN); Yanxue CHEN, Jinan (CN); Lihui BAI, Jinan (CN); Tie ZHOU, Jinan (CN); Xuejie XIE, Jinan (CN)

(21) Appl. No.: 17/488,664

(22) Filed: Sep. 29, 2021

(30) Foreign Application Priority Data
Jul. 9, 2021 (CN) 202110779625.2

(51) Int. Cl. H01L 43/04; H01L 27/22; H01L 43/06

(52) U.S. Cl. CPC H01L 43/04; H01L 27/222; H01L 43/06

(57) ABSTRACT

Disclosed are an artificial antiferromagnetic structure and a storage element. The artificial antiferromagnetic structure includes a first metal layer, an artificially synthesized antiferromagnetic layer and a second metal layer that are stacked in sequence, wherein there is an interfacial DM (Dzyaloshinskii-Moriya) interaction at an interface between the metal layer and the artificially synthesized antiferromagnetic layer, such that there is a first interfacial DM interaction between the first metal layer and the artificially synthesized antiferromagnetic layer, there is a second interfacial DM interaction between the second metal layer and the artificially synthesized antiferromagnetic layer, and the first interfacial DM interaction is different from the second interfacial DM interaction. The artificially synthesized antiferromagnetic layer forms a stable chiral Néel magnetic domain wall due to a strong interfacial DM interaction.

### TECHNICAL FIELD

The present disclosure relates to the field of information technology and spintronics, in particular to an artificial antiferromagnetic structure and a storage element.

### BACKGROUND

The artificial antiferromagnetic structure is structured such that two magnetic layers are coupled through interlayer exchange coupling via a non-magnetic layer located therebetween, and magnetic moments of the ferromagnetic layers are arranged antiparallelly under the action of interlayer exchange coupling. Due to the presence of a strong antiferromagnetic interlayer exchange coupling, the artificial antiferromagnetic structure has the advantages of small stray field, insensitiveness to disturbance by an external magnetic field and the like, and thus is widely used as a pinning layer in a spin valve or a magnetic tunnel junction, thereby promoting development of giant magnetoresistance sensors and tunneling magnetoresistance devices greatly. In recent years, as amazing physical phenomena such as magnetization reversal caused by spin orbit torque, fast domain wall movement and artificial spin ice are found in the artificial antiferromagnetic structure, people have realized that the artificial antiferromagnetic structure not only can be used as an auxiliary functional layer of a spintronic device, but also can become a carrier of a novel nonvolatile memory and spin logic device. In particular, owing to its high thermal stability, fast spin dynamic process and efficient magnetization reversal caused by the spin orbit torque, the perpendicularly magnetized artificial antiferromagnetic structure with strong antiferromagnetic coupling has a wide application prospect in the fields of high density information storage and terahertz and the like. To realize the deterministic magnetization reversal caused by the spin orbit torque in the perpendicularly magnetized artificial antiferromagnetic structure with strong antiferromagnetic coupling, an auxiliary magnetic field reaching up to 2000 Oe to 10000 Oe must be applied in the current direction, which becomes a bottleneck of the perpendicularly magnetized artificial antiferromagnetic structure with strong antiferromagnetic coupling being applied to the spintronics devices.

Thus, how to realize the controllable deterministic magnetization reversal by spin orbit torque in a low externally applied magnetic field or without the externally applied magnetic field becomes a technical problem demanding prompt solution.

### SUMMARY

In order to solve the technical problem of how to realize the controllable deterministic magnetization reversal by spin orbit torque with a low externally applied magnetic field or without the externally applied magnetic field, the present disclosure provides an artificial antiferromagnetic structure and a storage element to realize the controllable deterministic magnetization reversal by spin orbit torque in a low externally applied magnetic field or even without the externally applied magnetic field.

According to the first aspect, the embodiment of the application provides an artificial antiferromagnetic structure, including a first metal layer, an artificially synthesized antiferromagnetic layer and a second metal layer that are stacked in sequence, wherein a first interfacial Dzyaloshinskii-Moriya (DM) interaction exists between the first metal layer and the artificially synthesized antiferromagnetic layer, a second interfacial DM interaction exists between the second metal layer and the artificially synthesized antiferromagnetic layer, and the first interfacial DM interaction is different from the second interfacial DM interaction.

Optionally, the first metal layer and the second metal layer are different in material and/or thickness.

Optionally, the artificial antiferromagnetic structure further includes: a buffer layer stacked on a side of the first metal layer far away from the artificially synthesized antiferromagnetic layer, wherein a thickness of the first metal layer is greater than a thickness of the second metal layer.

Optionally, the first interfacial DM interaction is greater than the second interfacial DM interaction.

Optionally, the first metal layer includes any one of Ta, Pt, Ir, W, Mo, Pd, Au, CoPt, FePt, IrMn and PtMn.

Optionally, a thickness of the first metal layer ranges from 1 nm to 10 nm.

Optionally, the second metal layer includes one or more of Ru, Ta, Pt, W, Ti, Mo, Pd, Au, Cr, Cu and Hf.

Optionally, the second metal layer includes a compound layer with at least two metal layers, wherein a magnitude of the second interfacial DM interaction is regulated and controlled by changing a relative thickness and a sequence of the metal layers in the compound layer.

Optionally, the artificially synthesized antiferromagnetic layer includes a first ferromagnetic layer, a non-ferromagnetic layer and a second ferromagnetic layer that are stacked in sequence, wherein the first ferromagnetic layer and the second ferromagnetic layer form antiferromagnetic coupling via the non-ferromagnetic layer, magnetic moments in the first ferromagnetic layer and magnetic moments in the second ferromagnetic layer are arranged antiparallelly, and the first ferromagnetic layer and the second ferromagnetic layer are made of ferromagnetic materials with perpendicular magnetic anisotropy.

According to a second aspect, the embodiment of the present disclosure provides a storage element, including any one of the artificial antiferromagnetic structures in the first aspect.

According to the embodiment of the application, a first metal layer, an artificially synthesized antiferromagnetic layer and a second metal layer are stacked in sequence, wherein a first interfacial DM interaction exists between the first metal layer and the artificially synthesized antiferromagnetic layer, a second interfacial DM interaction exists between the second metal layer and the artificially synthesized antiferromagnetic layer, and the first interfacial DM interaction is different from the second interfacial DM interaction. The artificially synthesized antiferromagnetic layer forms a stable chiral Neel magnetic domain wall due to a strong interfacial DM interaction. When the first interfacial DM interaction and the second interfacial DM interaction are different in magnitude and/or direction, kinematic velocities of an up-to-down magnetic domain wall and a down-to-up magnetic domain wall in the chiral Neel magnetic domain wall are different under the application of a current accompanied with a relatively small auxiliary magnetic field or even a zero magnetic field, such that deterministic magnetization reversal caused by spin orbit torque is obtained.

Further, by regulating and controlling the thickness and/or material of the first metal layer and/or the second metal layer, the first interfacial DM interaction and the second interfacial DM interaction are different in magnitude and/or direction, such that kinematic velocities of an up-to-down magnetic domain wall and a down-to-up magnetic domain wall in the artificially synthesized antiferromagnetic layer are differentiated obviously.

Further, the artificially synthesized antiferromagnetic layer is composed of the first ferromagnetic layer, the non-ferromagnetic layer and the second ferromagnetic layer that are stacked in sequence, wherein the first ferromagnetic layer and the second ferromagnetic layer form antiferromagnetic coupling via the non-ferromagnetic layer, and the magnetic moments in the first ferromagnetic layer and the second ferromagnetic layer are arranged antiparallelly, such that the first ferromagnetic layer and the second ferromagnetic layer can achieve magnetization reversal as a whole under the action of the externally applied magnetic field or the spin orbit torque. Thus, when the DM interactions of the upper and lower interfaces of the artificially synthesized antiferromagnetic layer are different, kinematic velocities of the up-to-down magnetic domain wall and the down-to-up magnetic domain wall in the artificially synthesized antiferromagnetic layer are differentiated obviously. By applying a very small auxiliary magnetic field in the current direction, the magnetic moment directions of the perpendicular magnetized ferromagnetic layers can be reversed as a whole by means of the current induced spin orbit torque effect.

Further, the first ferromagnetic layer and the second ferromagnetic layer are made of ferromagnetic materials with perpendicular magnetic anisotropy. In order to enhance the perpendicular anisotropy of a ferromagnetic material, it is necessary to grow the ferromagnetic layer on a relatively thick metal layer. Thus, a stacked structure is structured such that the thicker first metal layer grows on the buffer layer, and the first ferromagnetic layer, the non-ferromagnetic layer and the second ferromagnetic layer in the artificially synthesized antiferromagnetic layer grow on the first metal layer in sequence, wherein the second metal layer thinner than the first metal layer grows on the second ferromagnetic layer, such that it is ensured that there is a relatively large difference between the DM interactions of the upper and lower interfaces of the artificially synthesized antiferromagnetic layer while ensuring that the ferromagnetic layer has better perpendicular anisotropy. Finally, the controllable deterministic magnetization reversal by spin orbit torque in a low externally applied magnetic field or without the externally applied magnetic field is realized.

### BRIEF DESCRIPTION OF THE DRAWINGS

The drawings described herein for further understanding of the present disclosure constitute a part of the present disclosure. The schematic embodiment and description thereof are used for explaining the present disclosure and do not limit the present disclosure improperly. In the drawings,

FIG. 1 is a structural schematic diagram of an artificial antiferromagnetic structure of an embodiment of the present disclosure;

FIG. 2 is another structural schematic diagram of an artificial antiferromagnetic structure of an embodiment of the present disclosure;

FIG. 3 is a normalized magnetic hysteresis loop and Hall resistance curve of the artificial antiferromagnetic structure of the embodiment of the present disclosure;

FIG. 4 is a relationship curve of Hall resistance changing along with current when the auxiliary magnetic field is applied to the artificial antiferromagnetic structure of the embodiment of the present disclosure.

### DETAILED DESCRIPTION

In order to understand technical features, objects and effects of the present disclosure more clearly, the specific embodiments of the present disclosure are illustrated with reference to drawings, and the same reference signs in the drawings represent parts that are same or similar in structure but same in function.

More specific details are described in the description below for the convenience of understanding the present disclosure fully. However, the present disclosure may further be implemented by other modes different from those described, such that the protection scope of the present disclosure is not limited to the specific embodiments of the description.

The embodiment of the application provides an artificial antiferromagnetic structure as shown in FIG. 1, which may include:

a first metal layer 10, an artificially synthesized antiferromagnetic layer 20 and a second metal layer 30 that are stacked in sequence, wherein a first interfacial DM interaction exists between the first metal layer 10 and the artificially synthesized antiferromagnetic layer 20, a second interfacial DM interaction exists between the second metal layer 30 and the artificially synthesized antiferromagnetic layer 20, and the first interfacial DM interaction is different from the second interfacial DM interaction. Exemplarily, the artificially synthesized antiferromagnetic layer 20, the first metal layer 10 and the second metal layer 30 form a sandwich structure. Usually, the DM interactions exist at interfaces between non-centrosymmetrical magnets and ferromagnets and metals, such that the first interfacial DM interaction exists at the interface between the artificially synthesized antiferromagnetic layer 20 and the first metal layer 10, the second interfacial DM interaction exists at the interface between the artificially synthesized antiferromagnetic layer 20 and the second metal layer 30, and the artificially synthesized antiferromagnetic layer 20 forms a stable chiral Neel magnetic domain wall due to a strong interfacial DM interaction. When the first interfacial DM interaction and the second interfacial DM interaction are different in magnitude and/or direction, kinematic velocities of an up-to-down magnetic domain wall and a down-to-up magnetic domain wall in the chiral Neel magnetic domain wall are different under the application of a current accompanied with a relatively small auxiliary magnetic field or even a zero magnetic field, such that deterministic magnetization reversal caused by spin orbit torque is obtained.

As an exemplary embodiment, the first metal layer 10 and the second metal layer 30 are different in material and/or thickness. By regulating and controlling the thickness and/or material of the first metal layer 10 and/or the second metal layer 30, the first interfacial DM interaction and the second interfacial DM interaction are different in magnitude and/or direction, such that kinematic velocities of an up-to-down magnetic domain wall and a down-to-up magnetic domain wall in the artificially synthesized antiferromagnetic layer 20 are differentiated obviously. For example, a metal layer with a greater thickness such as 1-10 nm may be adopted as the first metal layer 10, and a metal layer or a compound layer formed by stacking at least two metal layers with a smaller thickness such as 1-3 nm may be adopted as the second metal layer 30. As the first metal layer 10 and the second metal layer 30 are different in thickness and/or material, and the first metal layer 10 and the second metal layer 30 are both adjacent to the artificially synthesized antiferromagnetic layer 20, the first interfacial DM interface and the second interfacial DM interaction are different, such that the kinematic velocities of the chiral Neel magnetic domain wall in the artificial antiferromagnetic structure are different, and the kinematic velocities of the up-to-down magnetic domain wall and the down-to-up magnetic domain wall in the chiral Neel magnetic domain wall are differentiated obviously in a very small auxiliary magnetic field or even a zero magnetic field.

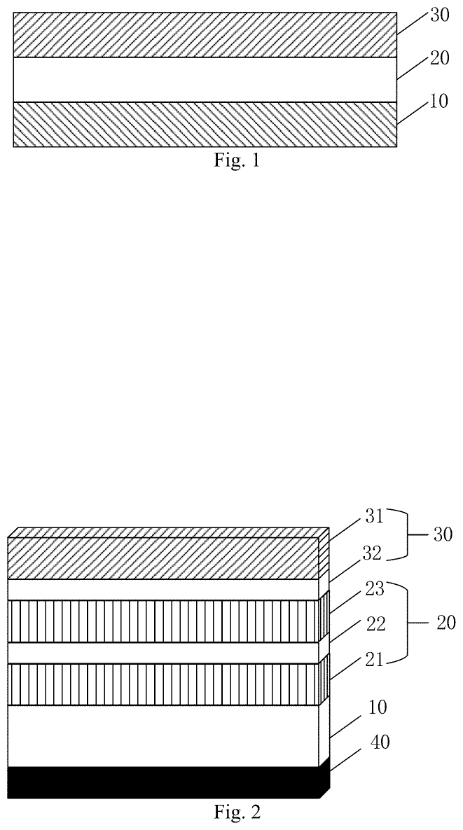

As an exemplary embodiment shown in FIG. 2, the artificially synthesized antiferromagnetic layer 20 includes a first ferromagnetic layer 21, a non-ferromagnetic layer 22 and a second ferromagnetic layer 23 that are stacked in sequence, wherein the first ferromagnetic layer 21 and the second ferromagnetic layer 23 form antiferromagnetic coupling via the non-ferromagnetic layer 22, magnetic moments in the first ferromagnetic layer 21 and magnetic moments in the second ferromagnetic layer 23 are arranged antiparallelly, and the first ferromagnetic layer 21 and the second ferromagnetic layer 23 are made of ferromagnetic materials with perpendicular magnetic anisotropy. Exemplarily, the ferromagnetic layer may be made of a ferromagnetic material with perpendicular magnetic anisotropy such as Co, Fe, Ni, CoFe, CoFeB, CoNi, CoPt, CoTb and FePt, and a thickness of the ferromagnetic layer ranges from 0.5 nm to 10 nm; and the first ferromagnetic layer 21 and the second ferromagnetic layer 23 may be same or different in making material and thickness. The non-ferromagnetic layer 22 may be made of one of Ta, Ru, Pt, Ti, W, Cr, Cu, Hf, Mo, Pd and Au and a thickness thereof ranges from 0.3 nm to 3 nm. As shown in FIG. 2, the second metal layer 30 includes a compound layer with at least two metal layers, and the compound layer includes a first compound layer 31 and a second compound layer 32 that are stacked in sequence, wherein a magnitude of the second interfacial DM interaction can be regulated and controlled by changing a relative thickness and a growing sequence of the first compound layer 31 and the second compound layer 32.

Description is made below by taking the first ferromagnetic layer 21 and the second ferromagnetic layer 23 being made of Co/Pt/Co, the non-ferromagnetic layer 22 being made of Ru, the first metal layer 10 being made of Pt and the second metal layer 30 being a Pt/Ta compound layer as an example:

In order to ensure perpendicular anisotropy of the ferromagnetic layer, it is necessary to grow the ferromagnetic layer on a thick metal layer. As the exemplary embodiment, the artificial antiferromagnetic structure further includes a substrate and a buffer layer 40 growing on the substrate. In this embodiment, the buffer layer 40 may be made of metals such as Ta, Cr, Ru, Ti and Al. The first metal layer 10 with a greater thickness, for example, 1-10 nm Pt (Pt being 5 nm may be taken as an example in this embodiment), grows on the buffer layer 40. The first ferromagnetic layer 21, the non-ferromagnetic layer 22 and the second ferromagnetic layer 23 in the artificially synthesized antiferromagnetic layer 20 grow on the first metal layer 10 in sequence, wherein the second metal layer 30, for example, 1 nm Pt and 2 nm Ta that grow in sequence, grows on the second ferromagnetic layer 23. As an exemplary embodiment, film layers in the artificially synthesized antiferromagnetic layer 20 can be grown by magnetron sputtering at room temperature. Exemplarily, the base pressure of the magnetron sputtering apparatus is superior to 1×10⁻⁸ torr, the sputtering gas is Ar, and a metal target can be used to grow the film layers by direct current sputtering.

Exemplarily, both the first metal layer 10 and the second metal layer 30 may generate spin currents, and the spin current of the first metal layer 10 acts on a lower ferromagnetic layer, i.e. the first ferromagnetic layer 21, of the artificially synthesized ferromagnetic layer 20, and the spin current of the second metal layer 30 acts on an upper ferromagnetic layer, i.e. the second ferromagnetic layer 23, of the artificially synthesized ferromagnetic layer 20. As the first metal layer 10 is thicker, the spin current in the first metal layer 10 is taken as a primary source of the spin current of the artificially synthesized antiferromagnetic layer 20.

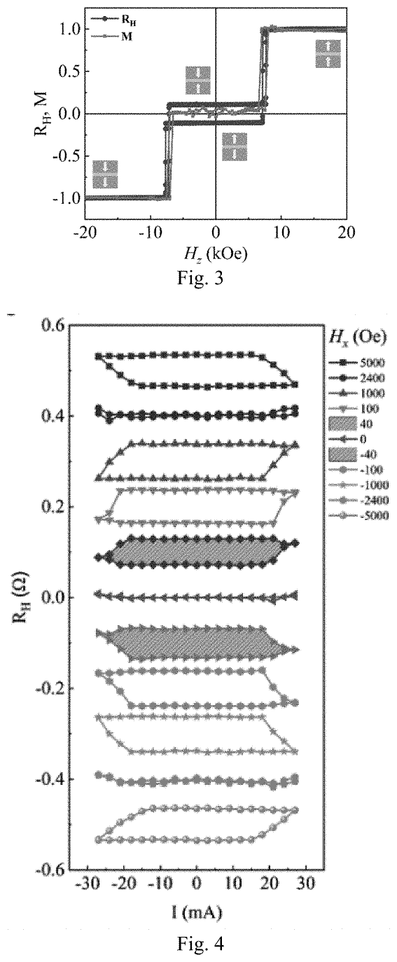

Exemplarily, the first ferromagnetic layer 21 and the second ferromagnetic layer 23 have remarkable perpendicular magnetic anisotropy, and the two ferromagnetic layers are coupled together via the non-ferromagnetic layer 22 located therebetween, so that the magnetism of the artificial antiferromagnetic structure is counteracted, and the stray field is very small, and will not interfere with an adjacent magnetic unit; and the anomalous Hall effect is not counteracted. FIG. 3 shows the normalized magnetic hysteresis loop (M) and Hall resistance (R_{H}) curves of the artificial antiferromagnetic structure when the external magnetic field is applied perpendicular to the film surface. And the arrangement directions (the arrangement directions of the magnetic moments of the two ferromagnetic layers in FIG. 3 are shown by arrows) of the magnetic moments of the two ferromagnetic layers in different magnetic fields are shown. It can be known from FIG. 3 that the artificial antiferromagnetic structure has remarkable perpendicular magnetic anisotropy, and the two ferromagnetic layers have strong antiferromagnetic coupling therebetween with the interlayer exchange coupling field reaching up to 7500 Oe; in a range of ±7500 Oe, the magnetism of the studied artificial antiferromagnetic sample is counteracted while the anomalous Hall resistance is not counteracted. Due to the presence of strong antiferromagnetic coupling, the magnetic moments in the upper and lower ferromagnetic layers are arranged antiparallelly. Thus, the two ferromagnetic layers can be subjected to magnetization reversal as a whole, that is, the magnetic moments in the upper and lower ferromagnetic layers reverse at the same time, and the magnetic moments after reversal are still arranged antiparallelly.

Exemplarily, when the first metal layer 10 is the Pt layer with the thickness above 5 nm and the first ferromagnetic layer 21 is a Co/Pt/Co layer, the effective field of the first interfacial DM interaction measured by experiment is 1300 Oe. When the thickness of the second metal layer 30 is smaller than that of the first metal layer 10 or is the Pt/Ta compound layer, the interfacial DM interaction between the second metal layer 30 and the second ferromagnetic layer 23 can be reduced effectively, such that the second interfacial DM interaction is smaller than the first interfacial DM interaction. Furthermore, the magnitude of the second interfacial DM interaction can be further regulated by changing the material in the second metal layer 30 and the thickness of the material, for example, changing the relative thickness and/or sequence of Pt and Ta. Exemplarily, when the thickness of Pt is 1 nm and the thickness of Ta is 2 nm, the effective field of the second interfacial DM interaction between the second ferromagnetic layer 23, i.e. the Co/Pt/Co layer and the second metal layer 30, i.e. the Pt/Ta layer is about 650 Oe. Thus, the first interfacial DM interaction and the second interfacial DM interaction will differ greatly when the first metal layer 10 and the second metal layer 30 are different in thickness and/or different in material or different in growing sequence of the material. Thus, the interfacial DM interaction between the artificially synthesized antiferromagnetic layer 20 and the two metal layers can be regulated and controlled to differ obviously by regulating and controlling the material and/or thickness of the first metal layer 10 and the second metal layer 30.

The interface between the first metal layer 10 and the first ferromagnetic layer 21 is an interface between the Pt layer and the Co/Pt/Co layer with a strong DM interaction, resulting in formation of the stable chiral Neel magnetic domain wall in the Co/Pt/Co layer. For example, a left-handed Neel magnetic domain wall can be formed in the Co/Pt/Co layer. FIG. 4 illustrates a relationship curve of Hall resistance changing along with current when different auxiliary magnetic fields are applied to the artificial antiferromagnetic structure of the embodiment in the current direction. It can be known from FIG. 4 that under a condition that the interfacial DM interactions between the artificially synthesized antiferromagnetic layer 20 and the two metal layers differ obviously, obvious magnetization reversal caused by spin orbit torque can be obtained by applying ±40 Oe auxiliary magnetic field. When the auxiliary magnetic field is a positive value, change of the Hall resistance along with current will be turned from anticlockwise (Hx<2400 Oe) to clockwise (Hx>2400 Oe).

When the magnetic domain wall in the artificial antiferromagnetic structure is the left-handed Neel wall and when the magnetic domain wall in the first ferromagnetic layer 21 is ↑←↓, and due to the presence of strong antiferromagnetic coupling, the domain wall of the corresponding second ferromagnetic layer 23 is ↓→↑, the magnetic domain walls in antiferromagnetic coupling may be called the first magnetic domain wall. In a similar way, when the magnetic domain wall in the first ferromagnetic layer 21 is ↓→↑, and the domain wall of the corresponding second ferromagnetic layer 23 is ↑←↓, the magnetic domain walls in antiferromagnetic coupling may be called the second magnetic domain wall. When the Hx of the auxiliary magnetic field is greater than 0 but smaller than 2400 Oe, the kinematic velocity of the first magnetic domain wall is greater than that of the second magnetic domain wall, resulting in anticlockwise magnetization reversal, and when the Hx of the auxiliary magnetic field is greater than 2400 Oe, the kinematic velocity of the second magnetic domain wall is greater than that of the first magnetic domain wall, resulting in clockwise magnetization reversal. When the externally applied auxiliary magnetic field is opposite and the corresponding Hx is smaller than −2400 Oe, the kinematic velocity of the first magnetic domain wall is greater than that of the second magnetic domain wall, resulting in anticlockwise magnetization reversal, and when the Hx is greater than −2400 Oe but smaller than 0, the kinematic velocity of the second magnetic domain wall is greater than that of the first magnetic domain wall, resulting in clockwise magnetization reversal.

The embodiment of the present disclosure further provides a storage element based on the artificially synthesized antiferromagnetic layer described in the embodiment. By means of the artificially synthesized antiferromagnetic structure described in the embodiment, deterministic magnetization reversal caused by spin orbit torque can be realized without applying the auxiliary magnetic field.

At this point, the technical solution of the disclosure has been described in combination with a plurality of embodiments above. However, those skilled in the art are easy to understand that the protection scope of the disclosure is not merely limited to these specific embodiments. Those skilled in the art can either split and combine the technical solutions in the embodiments or make equivalent modifications or replacements to related technical features without departing from the technical principle of the disclosure. Any changes, equivalent replacements, improvements and the like made within the technical concept and/or the technical principle of the disclosure will fall within the protection scope of the disclosure.

All embodiments in the description are described progressively, reference is made to same and similar parts of the embodiments, and each embodiment puts emphasis on difference from other embodiments. In particular, as far as the system embodiment is concerned, as the system embodiment is substantially similar to the method embodiment, thus being described simply. The related part refers to description of part of the method embodiment.

The above is merely the embodiments of the present disclosure and is not used to limit the present disclosure. For those skilled in the art, various changes and variations can be made to the present disclosure. Any modification, equivalent replacements, improvement, etc. made within the spirit and principle of the present disclosure shall be included in the scope of the claims of the present disclosure.

What is claimed is:

1. An artificial antiferromagnetic structure, comprising:
a first metal layer, an artificially synthesized antiferromagnetic layer and a second metal layer that are stacked in sequence, wherein
a first interfacial DM interaction exists between the first metal layer and the artificially synthesized antiferromagnetic layer, a second interfacial DM interaction exists between the second metal layer and the artificially synthesized antiferromagnetic layer, and
the first interfacial DM interaction is different from the second interfacial DM interaction.

2. The artificial antiferromagnetic structure according to claim 1, wherein
the first metal layer and the second metal layer are different in material and/or thickness.

3. The artificial antiferromagnetic structure according to claim 2, further comprising:
a buffer layer stacked on a side of the first metal layer far away from the artificially synthesized antiferromagnetic layer, wherein
a thickness of the first metal layer is greater than a thickness of the second metal layer.

4. The artificial antiferromagnetic structure according to claim 1, wherein
the first interfacial DM interaction is greater than the second interfacial DM interaction.

5. The artificial antiferromagnetic structure according to claim 1, wherein the first metal layer comprises any one of Ta, Pt, Ir, W, Mo, Pd, Au, CoPt, FePt, IrMn and PtMn.

6. The artificial antiferromagnetic structure according to claim 1, wherein the thickness of the first metal layer ranges from 1 nm to 10 nm.

7. The artificial antiferromagnetic structure according to claim 1, wherein the second metal layer comprises one or more of Ru, Ta, Pt, W, Ti, Mo, Pd, Au, Cr, Cu and Hf.

8. The artificial antiferromagnetic structure according to claim 7, wherein the second metal layer comprises a compound layer with at least two metal layers, and wherein a magnitude of the second interfacial DM interaction is regulated and controlled by changing a relative thickness and a sequence of the metal layers in the compound layer.

9. The artificial antiferromagnetic structure according to claim 1, wherein the artificially synthesized antiferromagnetic layer comprises:
a first ferromagnetic layer, a non-ferromagnetic layer and a second ferromagnetic layer that are stacked in sequence, wherein the first ferromagnetic layer and the second ferromagnetic layer form antiferromagnetic coupling via the non-ferromagnetic layer, magnetic moments in the first ferromagnetic layer and magnetic moments in the second ferromagnetic layer are arranged antiparallelly, and the first ferromagnetic layer and the second ferromagnetic layer are made of ferromagnetic materials with perpendicular magnetic anisotropy.

10. (canceled)
